(19) United States
(12) Patent Application Publication
(10) Pub. No.: US 2013/0295736 A1
(43) Pub. Date: Nov. 7, 2013

(54) FABRICATION METHOD OF TRENCH POWER SEMICONDUCTOR STRUCTURE

(71) Applicant: HSIU-WEN HSU, HSINCHU COUNTY (TW)

(72) Inventor: HSIU-WEN HSU, HSINCHU COUNTY (TW)

(73) Assignee: SUPER GROUP SEMICONDUCTOR CO., LTD., NEW TAIPEI CITY (TW)

(21) Appl. No.: 13/464,913

(22) Filed: May 4, 2012

(51) Int. Cl. H01L 21/336

(52) U.S. Cl. 438/270; 257/E21.41

(57) ABSTRACT

A fabrication method of a trench power semiconductor structure is provided. First, a substrate with a first epitaxial layer is provided. Then, a dielectric layer is formed on the first epitaxial layer. A shielding layer is formed on the dielectric layer. Next, a portion of the shielding and the dielectric layers are removed to form a shielding structure and a dielectric structure on the first epitaxial layer, wherein the shielding structure is stacked on the dielectric structure. A selective epitaxial growth technique is utilized to form a second epitaxial layer surrounding the dielectric and the shielding structures on the exposed surface of the first epitaxial layer and the second epitaxial layer. Afterward, the shielding structure is removed to form a trench on the dielectric structure. A gate oxide layer is further formed on the inner surface of the trench. Lastly, a conducting structure is formed in the trench.

### BACKGROUND

1. Technical Field

The present invention relates to a fabrication method of a power semiconductor structure, and in particular, to a fabrication method of a trench power semiconductor structure.

2. Description of Related Art

In the high frequency application field of semiconductor devices, it's important to improve the switching speed thereof Thus, the switching loss can be reduced while the efficiency can be increased. In order to effectively reduce the switching loss, one of the conventional methods is to form thick bottom oxide in the trench for having a low gate-to-drain capacitance. The conventional process for forming the bottom oxide in the trench is complicated and the thickness of the bottom oxide is hard to be controlled.

FIG. 1A to FIG. 1B schematically illustrates a traditional fabrication method of a trench semiconductor structure. First, as shown in FIG. 1A, a lightly doped N-type epitaxial layer 110 is formed on a heavily doped N-type substrate 100. Next, a plurality of trenches 120 is formed in the epitaxial layer 110. Then, an oxide layer is deposited in the trenches 120 and on the lightly doped N-type epitaxial layer 110. Remove a portion of the oxide layer in the trenches 120 and the oxide layer on the lightly doped N-type epitaxial layer 110 are removed by the etching back method so as to respectively form a bottom oxide 130 in the each trench 120.

Next, referring to FIG. 1B, a gate oxide layer 140 is formed on the inner surface of the trenches 120 as well as on the lightly doped N-type epitaxial layer 110. Then, a gate poly 150 is formed in each trench 120. Afterward, a P-type body region 160 is formed in the lightly doped N-type epitaxial layer 110 and a heavily doped N-type source region 170 is formed in the upper portion of the lightly doped N-type epitaxial layer 110.

In the above-mentioned traditional fabrication method of the trench semiconductor structure, the oxide etching back method has to be applied for removing the unnecessary oxide layer to obtain the oxide layer of desired thickness in the step of forming the bottom oxide 130. As the etching speed is hard to control and often results in either over etching or insufficient etching causing the thickness of the bottom oxide 130 hard to be controlled. Furthermore, the step of the etching back may destroy the bottom oxide as well as cause uneven thickness thereof Above-mentioned issues would in practice generate unexpected value of the gate to drain capacitance. For example, if the thickness of the bottom oxide is too thin, the gate to drain capacitance may not be lowered consequently, unable to achieve the effect of reducing the switching loss. Conversely, if the thickness of the bottom oxide is too thick, the conduct impedance would increase resulting in channel failure.

### SUMMARY

Accordingly, a main objective of the present invention is to provide a fabrication method of a trench power semiconductor structure, in which the process is simple while the thickness of the bottom oxide in the trench may be exactly controlled. Therefore the issues of over etch, insufficient etch, destruction of bottom oxide and uneven thickness issues caused in the etching back process may be prevent. Consequently, the gate to drain capacitance with a predetermined value can be achieved while the gate charge may be reduced so as to decrease the switching loss.

To achieve the above-mentioned objective, the present invention is to provide a fabrication method of a power semiconductor structure. First, a substrate is provided. Then, a first epitaxial layer is formed on the substrate. A dielectric layer is formed on the first epitaxial layer. A shielding layer is formed on the dielectric layer. Next, a portion of the shielding layer and the dielectric layer are removed so as to respectively form a shielding structure and a dielectric structure on the first epitaxial layer, wherein the shielding structure is stacked on the dielectric structure. Then, a selective epitaxial growth technique is utilized to form a second epitaxial layer surrounding the dielectric and the shielding structures on the exposed surface of the first epitaxial layer. Afterward, the shielding structure is removed to form a trench on the dielectric structure. A gate oxide layer is formed on the inner surface of the trench. Lastly, a conducting structure is formed in the trench. The second epitaxial layer has a body region and a source region.

### BRIEF DESCRIPTION OF THE DRAWINGS

The present invention will now be specified with reference to its preferred embodiments illustrated in the following drawings, in which:

FIG. 1A to FIG. 1B schematically illustrates a traditional fabrication method of a trench semiconductor structure.

FIG. 2A to FIG. 2E schematically illustrates a fabrication method of a trench power semiconductor structure according to a first embodiment of the present invention.

FIG. 3A to FIG. 3C schematically illustrates a fabrication method of a trench power semiconductor structure according to a second embodiment of the present invention.

FIG. 4A to FIG. 4B schematically illustrates a fabrication method of a trench power semiconductor structure according to a third embodiment of the present invention.

FIG. 5 schematically illustrates a fabrication method of a trench power semiconductor structure according to a forth embodiment of the present invention.

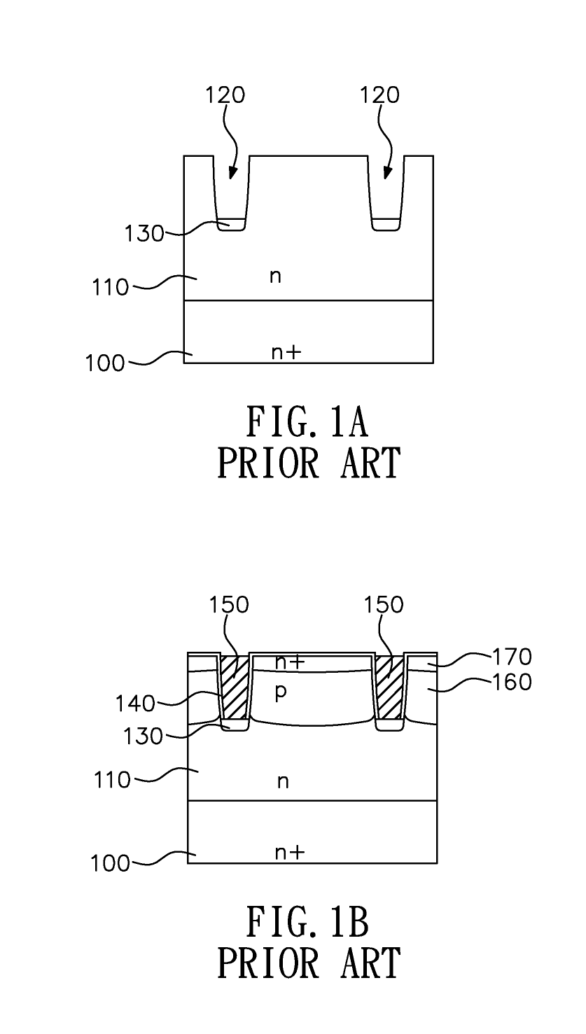

### DESCRIPTION OF THE EXEMPLARY EMBODIMENTS

The technological feature of the present invention is to form a dielectric layer having a predetermine thickness on a first epitaxial layer. Since the growth speed of the dielectric layer is easy to be controlled, desired thickness of the dielectric layer may be exactly formed on the first epitaxial layer. As the predetermine thickness of the dielectric layer can be formed on the first epitaxial layer, a shielding layer can then be formed on the dielectric layer. Consequently, the step of etching dielectric layer may be prevented in the present invention. The exact value and even thickness of the dielectric layer may be achieved in the bottom of the gate trench. Therefore, the damage of the dielectric layer due to etching step may be avoided.

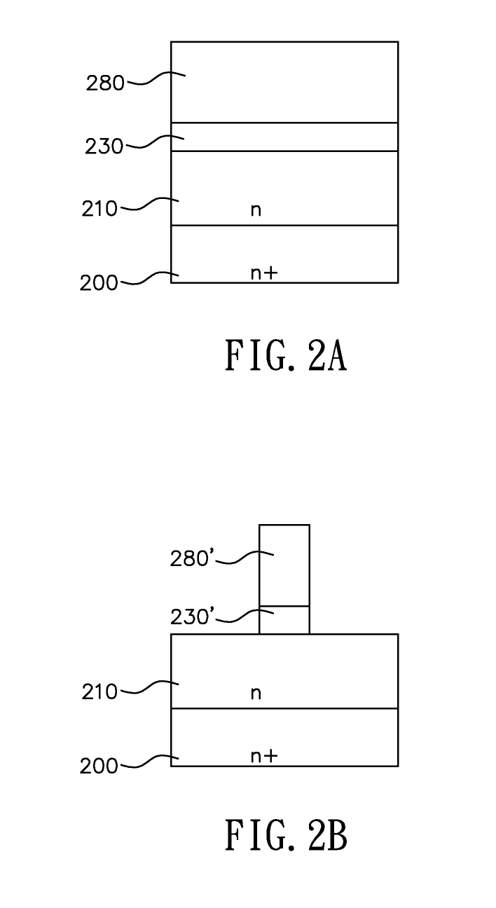

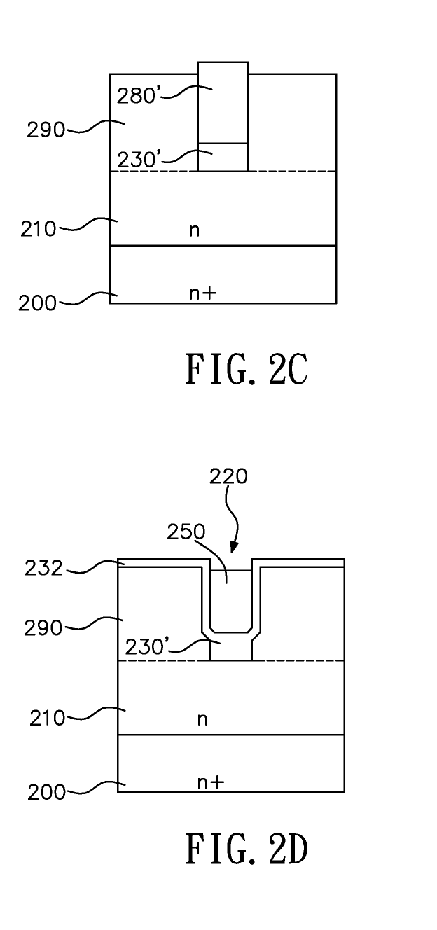

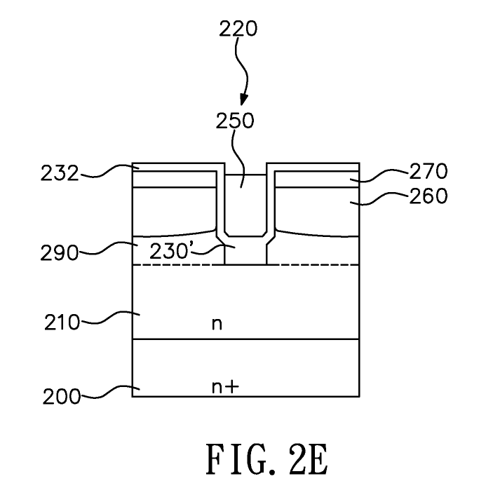

FIG. 2A to FIG. 2E schematically illustrates a fabrication method of a trench power semiconductor structure according to a first embodiment of the present invention. Firstly, referring to FIG. 2A, a heavily doped N-type substrate 200 (hereinafter referred to as the substrate 200) is provided. Then, a lightly doped N-type first epitaxial layer 210 (hereinafter referred to as the first epitaxial layer 210) is formed on the substrate 200. The N-type doped is used in the instant embodiment. However, the present invention is not limited thereto. Next, a depositing method is utilized to form a dielectric layer 230 on the first epitaxial layer 210. Then, a shielding layer 280 is formed on the dielectric layer 230. Another implementation of forming the dielectric layer 230 may be through using the reaction of gas with the first epitaxial layer 210 so as to form the dielectric layer 230 on the first epitaxial layer 210. The above-mentioned shielding layer 280 and dielectric layer 230 may comprise of different material. For example, when the dielectric layer 230 comprise of silicon oxide, silicon nitride would be chosen for the shielding layer 280. Therefore, in the following step of forming trench on the dielectric structure, the selective etching method would be utilized to just remove the shielding structure on the dielectric structure so as to maintain the dielectric structure with predetermined thickness.

Next, referring to FIG. 2B, a photoresist layer is formed on the shielding layer 280 to define a pattern layer which is used for forming the width and the position of the trench. Then, use the pattern layer as an etching mask to etch the shielding layer 280 and dielectric layer 230 so as to form a shielding structure 280′ as well as a dielectric structure 230′ on the first epitaxial layer 210. The shielding structure 280′ is stacked on the dielectric structure 230′. The width of the shielding structure 280′ may be substantially the same as the width of the dielectric structure 230′. However, the present invention is not limited to thereto.

Then, referring to FIG. 2C, a selective epitaxial growth technique is utilized to form a second epitaxial layer 290 on the first epitaxial layer 210, wherein the second epitaxial layer 290 covers the exposed surface of the first epitaxial layer 210 while surrounds the dielectric structure 230′ and shielding structure 280′. The thickness of the second epitaxial layer 290 must be larger than the thickness of the dielectric structure 230′ so as to facilitate the step of forming trench on the dielectric structure 230′. The second epitaxial layer 290 and the first epitaxial layer 210 in the instant embodiment are of identical material and with same type dopant. However, the present invention is not limited to thereto, i.e., the second epitaxial layer 290 and the first epitaxial layer 210 may comprise of different material and with different type dopant.

Next, referring to FIG. 2D, remove the shielding structure 280′ to form a trench 220 on the dielectric structure 230′. Since the shielding structure 280′ and dielectric structure 230′ are of different material, the selective etching method may be utilized to only remove the shielding structure 280′ while keep the dielectric structure 230′. Consequently, the dielectric structure 230′ of predetermined thickness is kept and the dielectric structure 230′ would not be damaged. Next, a gate oxide layer 232 is formed on the inner surface of the trench 220 and the exposed surface of the second epitaxial layer 290. Then, a conducting structure 250 is formed in the trench 220. Afterward, referring to FIG. 2E, an ion implantation method is utilized to form a body region 260 in the second epitaxial layer 290. A source region 270 is formed in an upper portion of the body region 260 via the ion implantation method.

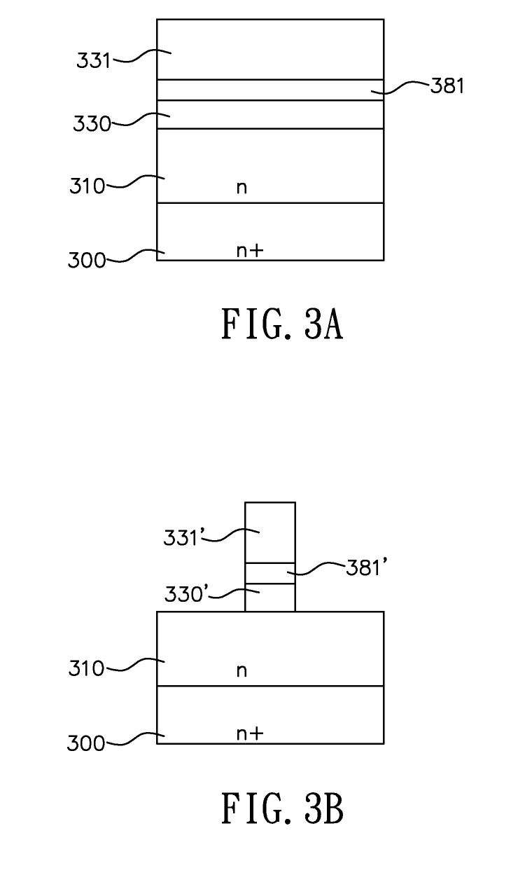

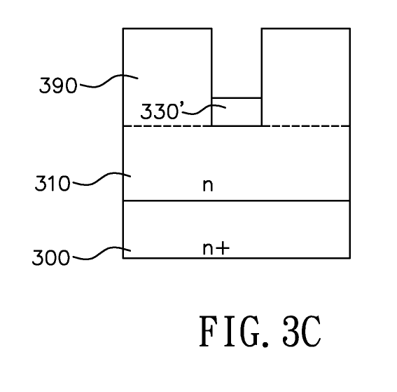

FIG. 3A to FIG. 3C schematically illustrates a fabrication method of a trench power semiconductor structure according to a second embodiment of the present invention. The difference between the second embodiment and the first embodiment is that only a shielding layer 280 formed on the dielectric layer 230 so as to form double layer stacked structure on the first epitaxial layer 210 in the first embodiment, wherein the double layer stacked structure includes the shielding structure 280′ and the dielectric structure 230′. In the second embodiment, a multi-layer structure may be formed on the first epitaxial layer. Referring to FIG. 3A, a lightly doped n-type first epitaxial layer 310 (hereinafter referred to as the first epitaxial layer 310) is formed on a heavily doped N-type substrate 300 (hereinafter referred to as the substrate 300). Next, a dielectric layer 330 is formed on the first epitaxial layer 310. Afterward, an etch stop layer 381 is formed on the dielectric layer 330. A covering layer 331 is further formed on the etch stop layer 381. The etch stop layer 381 and the covering layer 331 may serve as the shielding layer 280 of the first embodiment.

The above-mentioned dielectric layer 330 and covering layer 331 may comprise of oxide while the etch stop layer 381 may comprise of silicon nitride, for facilitating the step of removing the etch stop layer 381 and covering layer 331 using the selective etching method. However, the present invention is not limited to above-mentioned material so long as the material selected for the etch stop layer 381 is chosen different from the dielectric layer 330 and covering layer 331.

Next, referring to FIG. 3B, a photoresist material is formed on the covering layer with the lithography carried out afterward to define the width of the covering layer 331, wherein the width of the covering layer 331 is also the width of the trench formed in the following step. An anisotropic etching method is utilized to etch the covering layer 331 so as to form a covering structure 331′. Then, the covering structure 331′ is used as the etching mask to sequentially anisotropically etch the etch stop layer 381 and the dielectric layer 330 so as to respectively form a etch stop structure 381′ and a dielectric structure 330′ stacking on the first epitaxial layer 310.

Next, referring to FIG. 3C, a selective epitaxial growth technique is utilized to form a second epitaxial layer 390 on the first epitaxial layer 310. Then, sequentially remove the covering structure 331′ and etch stop structure 381′. The rest of steps in the present embodiment are essentially the same as the steps described in the first embodiment, and further descriptions are hereby omitted.

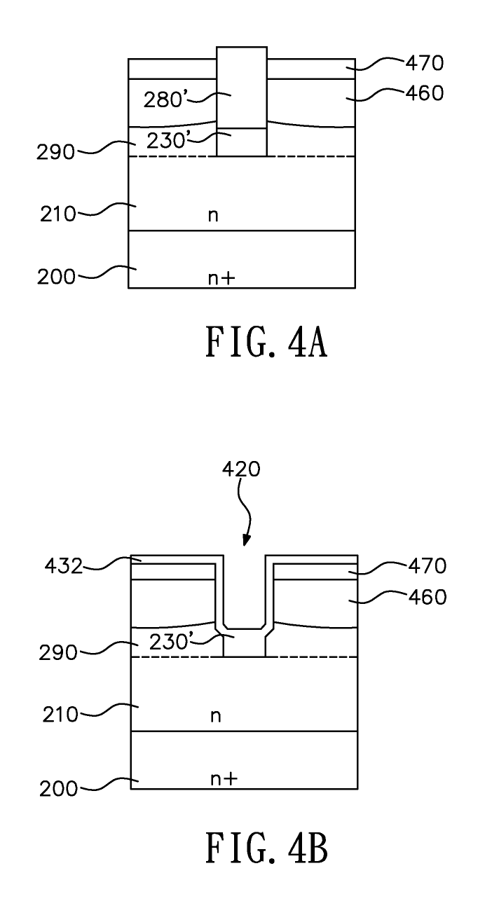

FIG. 4A to FIG. 4B schematically illustrates a fabrication method of a trench power semiconductor structure according to a third embodiment of the present invention. The difference between the first embodiment and the present embodiment is the step of forming the source region 270 in the body region 260. The step of forming the source region 270 is performed after the step of forming the gate oxide layer 232 in the first embodiment. Whereas in the present embodiment, the step of forming the source region 270 is performed before the step of forming the gate oxide layer 232.

Referring to FIG. 4A, the step follows the step of FIG. 2C in which the second epitaxial layer 290 is formed. Then, an ion implantation method is utilized to form a body region 460 in the second epitaxial layer 290. Next, a source region 470 is formed in an upper portion of the body region 460.

Next, referring to FIG. 4B, the shielding structure 280′ is removed to form a trench 420 on the dielectric structure 230′. Then, a gate oxide layer 432 is formed both on the inner surface of the trench 420 and the exposed surface of the second epitaxial layer 290. The rest of steps in the present embodiment are essentially the same as the steps described in the first embodiment, and further descriptions are hereby omitted.

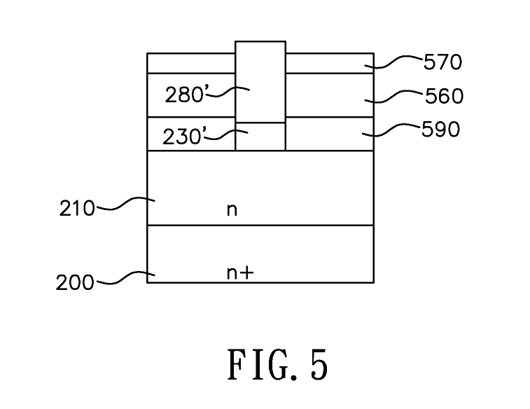

FIG. 5 schematically illustrates a fabrication method of a trench power semiconductor structure according to a forth embodiment of the present invention. The difference between the first embodiment and the present embodiment is in the forming method of the body region 260 and the source region 270. The body region 260 and the source region 270 are formed using ion implantation in the first embodiment. Whereas in the present embodiment, an epitaxial method is utilized to form the body region 560 and the source region 570.

Referring to FIG. 5, the described step follows the step of FIG. 2B, in which the shielding structure 280′and the dielectric structure 230′ are formed. Then, a selective epitaxial growth technique is utilized to form an N-type third epitaxial layer 590 (hereinafter referred to as the third epitaxial layer 590) on the first epitaxial layer 210. Next, a selective epitaxial growth technique is utilized to form a second epitaxial layer on the third epitaxial layer 590, wherein the second epitaxial layer comprises of a P-type body region 560 (hereinafter referred to as the body region 560) and a N-type source region 570 (hereinafter referred to as the source region 570). The above-mentioned the source region 570 may be formed in an upper portion of the body region 560 via the ion implantation method or may be formed on the body region 560 via the epitaxial method. The thickness of the third epitaxial layer 590 must be larger than the thickness of the dielectric structure 230′.

While the preferable embodiments of the present invention have been set forth for the purpose of disclosure, without any intention to limit the scope of the present disclosure thereto. Modifications of the disclosed embodiments of the present invention as well as other embodiments thereof may occur to those skilled in the art. Accordingly, the appended claims are intended to cover all embodiments which do not depart from the spirit and scope of the present invention.

1. A fabrication method of a trench power semiconductor structure comprising:
providing a substrate;
forming a first epitaxial layer on the substrate;
forming a dielectric layer on the first epitaxial layer;
forming a shielding layer directly disposed on the dielectric layer, wherein the shielding layer and the dielectric layer are different materials;
removing a portion of the shielding layer and the dielectric layer so as to respectively form a shielding structure and a dielectric structure on the first epitaxial layer, wherein the shielding structure is stacked on the dielectric structure;
utilizing a selective epitaxial growth technique to form a second epitaxial layer surrounding the dielectric structure and the shielding structure on the exposed surface of the first epitaxial layer;
removing the shielding structure to form a trench directly disposed on the dielectric structure;
forming a gate oxide layer on the inner surface of the trench; and
forming a conducting structure in the trench after forming the gate oxide layer on the inner surface of the trench;
wherein the second epitaxial layer has a body region and a source region.

2. A fabrication method of a trench power semiconductor structure of claim 1, wherein the shielding layer and the dielectric layer comprise of different material.

3. A fabrication method of a trench power semiconductor structure of claim 1, wherein the step of removing a portion of the shielding layer and the dielectric layer are completed using a same mask so that the width of the shielding structure and the width of the dielectric structure are substantially the same.

4. A fabrication method of a trench power semiconductor structure of claim 1, wherein the step of removing a portion of the shielding layer and the dielectric layer is implemented by etching a portion of the shielding layer to form the shielding structure and using the shielding structure as an etching mask to etch a portion of the dielectric layer so as to form the dielectric structure.

5. A fabrication method of a trench power semiconductor structure of claim 4, wherein the step of removing the shielding structure is to utilize a selective etching method to remove the shielding structure.

6. A fabrication method of a trench power semiconductor structure of claim 1, wherein the shielding layer comprises an etch stop layer and a covering layer.

7. A fabrication method of a trench power semiconductor structure of claim 6, wherein the covering layer and the dielectric layer comprise an oxide while the etch stop layer comprises of a silicon nitride.

8. A fabrication method of a trench power semiconductor structure of claim 1, wherein the steps of forming the body region and source region are implemented after the step of forming the gate oxide layer.

9. A fabrication method of a trench power semiconductor structure of claim 1, wherein the body region or the source region is formed in the second epitaxial layer using an ion implantation method.

10. A fabrication method of a trench power semiconductor structure of claim 1, wherein the body region or the source region is formed in the second epitaxial layer using an epitaxial growth method.
